(19) United States
(12) Patent Application Publication
(10) Pub. No.: US 2025/0150015 A1
(43) Pub. Date: May 8, 2025

(54) Method for monitoring an electrical machine, inverter arrangement and drive system

(71) Applicant: SEG Automotive Germany GmbH, Stuttgart (DE)

(72) Inventors: Johannes RAUHUT, Stuttgart (DE); Arunkumar Motaganahalli Srinivasamurthy, Stuttgart (DE)

(21) Appl. No.: 18/939,233

(22) Filed: Nov. 6, 2024

(30) Foreign Application Priority Data
Nov. 8, 2023 (DE) 102023131008.9

(51) Int. Cl. H02P 29/024; G01R 31/34

(52) U.S. Cl. CPC H02P 29/024; G01R 31/343; G01R 31/346

(57) ABSTRACT

An electrical machine has a stator, which has at least three phase windings, and a rotor. A method for monitoring the electrical machine includes, that a current flowing through each of the at least three phase windings is measured and a rationality factor is determined for each of the at least three phase windings as a function of squares of the measured currents. Subsequently, the determined rationality factors for each of the at least three phase windings are compared with at least one threshold value and, depending on the result of the comparison, it is determined whether there is a fault in the electrical machine. The disclosure also relates to a computing unit which is configured to carry out the method, as well as to an inverter arrangement and a drive system.

### CROSS-REFERENCE TO RELATED APPLICATIONS

This application claims priority to German Patent Application No. 102023131008.9 filed Nov. 8, 2023 which is hereby incorporated by reference in its entirety.

### TECHNICAL FIELD

The present disclosure relates to a method for monitoring an electrical machine as well as a computing unit, a computer program, an inverter arrangement and a drive system for carrying out the method.

### BACKGROUND

In multiphase electric drive systems, especially for vehicles that have a multiphase electric machine (i.e. an electric machine having multiple phase windings) and a power converter or inverter to control it, the phase current (i.e. the current through a phase winding of the stator of the electric machine) provided by the inverter can be measured by a phase current sensor to control and monitor the torque.

To ensure correct torque delivery and control, faults in the phase current sensors as well as different types of potential short circuits, e.g. within a phase winding between stacks of windings and between two phase windings, should be detected in the electrical machine. Any error can lead to an incorrect calculation of the current operating point of the drive system and subsequently to dangerous behavior in generating excessive torque. This must be prevented from the point of view of product and functional safety.

Various methods are known for monitoring a drive system. For example, it is possible to check whether the sum of all phase currents is zero. However, this does not detect faults within the electrical machine, as the currents are balanced even in the event of short circuits.

More complex models can also be used to detect faults in the electrical machine or the inverter from the currents. It may also be necessary to inject an additional excitation into the circuit.

U.S. Pat. No. 10,955,446 B2 shows a method for determining the phase currents of an electrical machine with an inverter and a stator comprising stator windings with a number of phases of at least three. The phase currents of a number of measurement phases, which is at least two, are measured, wherein the phase currents of the measurement phases are measured in each case in a measurement interval, when the active switching elements assigned to the measurement phases in a low-side path of the inverter are controlled in a switching interval which is limited by a switch-on time and a switch-off time. The phase currents of the remaining phases are determined computationally from the measured phase currents in such a way that at least the measured phase currents, a spatial angle of the measured phases and a spatial angle of the remaining phases are used for the computational determination, wherein the measurement interval is selected in such a way that it does not comprise a switch-on time or a switch-off time of at least one of the active switching elements of the inverter assigned to the phases of the stator.

### SUMMARY

According to the disclosure, a method for monitoring an electrical machine, a computing unit, a computer program, an inverter arrangement and a drive system for carrying out the method are proposed with the features of the independent patent claims. Advantageous embodiments are the subject of the dependent claims and the following description.

The disclosure is based on an electric machine that is used, for example, as part of a drive system, in particular of a vehicle. The electrical machine has a stator and a rotor. The stator has at least three phase windings. The electrical machine is, for example, a three-phase machine, such as a synchronous machine or an asynchronous machine, which is operated with a multiphase alternating current, for example a three-phase alternating current, which oscillates between a minimum and maximum value (current intensity) within a period duration.

A gist is that, depending on the currents flowing through the at least three phase windings, rationality factors, which express a ratio of the squared current values to each other, are determined, on the basis of which a fault in the electrical machine is determined. This makes it possible to detect faults in the electrical machine, in particular short circuits within a phase winding between the winding stacks of a winding or between two phase windings as well as offset faults or gain faults in one or more of the phase currents, with little computational effort without additional current injections, but based on the existing sensor signals.

Furthermore, the method can also be used in particular in three-phase or multiphase drive systems with an electric machine and an inverter arrangement.

Specifically, a current flowing through each of the at least three phase windings is measured, squared and a rationality factor is determined for each phase winding as a function of the squares of the measured currents. The rationality factors are determined for each phase winding, in particular as the quotient between the square of the current measured in the phase windings and a sum of the squares of the currents measured in the other phase windings. In particular, the following equations can be used for this purpose:

$${r}_{x} = \frac{{i}_{x}^{2}}{{\sum }_{j = 1}^{n} ( {i}_{j}^{2} ) - {i}_{x}^{2}} \qquad ( 1 )$$

With rₓ the rationality factor of the phase winding x, iₓ the current through the phase winding x and n the number of phase windings of the electrical machine.

For a three-phase electrical machine with the phase windings U, V and W, this results in

$${r}_{U} = \frac{{i}_{U}^{2}}{{i}_{W}^{2} + {i}_{V}^{2}} \qquad ( 2 )$$

$${r}_{V} = \frac{{i}_{V}^{2}}{{i}_{W}^{2} + {i}_{U}^{2}} \qquad ( 3 )$$

$${r}_{W} = \frac{{i}_{W}^{2}}{{i}_{V}^{2} + {i}_{u}^{2}} \qquad ( 4 )$$

Since the currents measured by the current sensors are time-dependent variables, in particular the time-dependent currents, the rationality factors are also time-dependent.

The determined rationality factors for each of the at least three phase windings are then compared with at least one threshold value and, depending on the result of the comparison, it is determined whether there is a fault in the electrical machine.

In particular, the waveforms of all specific rationality factors are compared with a first and/or a second threshold value. The first threshold value is, for example, a maximum value and the second threshold value is a minimum value. The first threshold value is higher than the second threshold value. The exact numerical values for the first and second threshold values depend in particular on the number of phase windings of the electrical machine and/or the measurement tolerances of the current sensors and/or an electrical slip of the electrical machine.

In a theoretical, fault-free, three-phase drive system, i.e. in a three-phase drive system that is not subject to any of the above-mentioned influences of a real system, the rationality factor oscillates between a value of 0 and 2. In this case, the first threshold value could, for example, have a value of 2, while the second threshold value could have a value that is infinitesimally below 2.

For a real three-phase drive system, for example, the second threshold value can have a value of 1.8 or 1.9, while the first threshold value can have a value of 2.2 or 2.1. The first and second threshold values can be adjusted over time, in particular due to ageing of the components.

If it is determined that one or more of the rationality factors exceed the first threshold, it is determined that there is a fault in the electrical machine. This can be expressed as follows:

$${r}_{x} \leq {S}_{high} \qquad ( 5 )$$

with the first threshold value S_{high}.

If it is determined that not all rationality factors exceed the second threshold value at least once in a given period of time, which in particular corresponds to at least one period length of the current waveform, it is also determined that there is a fault in the electrical machine. This can be expressed as follows:

$${r}_{x} > {S}_{low} \qquad ( 6 )$$

with the second threshold value S_{low}.

If, on the other hand, all rationality factors fulfill both conditions shown in equations (5) and (6), i.e. it is determined that no rationality factor exceeds the first threshold value and each rationality factor exceeds the second threshold value at least once in the predetermined time period, there is no fault in the electrical machine.

The advantages mentioned above can be achieved using this method.

If it is determined that there is a fault in the electrical machine, the electrical machine is switched to a safe state. For example, the current supplied to the electrical machine can be limited in each phase winding or a phase short circuit or ground short circuit can be generated in all phase windings for which a fault has been determined by closing, for the faulty phase winding or the faulty phase windings, all switches of a high side or a low side of an inverter arrangement, via which the electrical machine is supplied with power. This allows the electrical machine to continue operating after a fault has been detected in it, for example to transport the vehicle to a workshop where the exact fault can be determined and rectified. It is also possible to cause a short circuit of all phase windings (so-called ASC, active short circuit).

A computing unit according to the disclosure, e.g. a control unit of a vehicle, is configured, in particular in terms of programming, to carry out a method according to the disclosure.

The disclosure also relates to an inverter arrangement for controlling a multiphase electrical machine, having a half-bridge and a current sensor for each phase winding of the electrical machine, which is configured to measure a current flowing through the phase winding, and a computing unit which is configured to carry out a method according to the disclosure.

The disclosure also relates to a drive system with a multiphase electrical machine and an inverter arrangement.

The implementation of a method according to the disclosure in the form of a computer program or computer program product with program code for carrying out all method steps is also advantageous, since this results in particularly low costs, especially if an executing control unit is still used for other tasks and is therefore available anyway. Finally, a non-transitory machine-readable storage medium is provided with a computer program stored on it as described above. Suitable storage media or data carriers for providing the computer program are, in particular, magnetic, optical and electrical memories, such as hard disks, flash memories, EEPROMs, DVDs, etc. It is also possible to download a program via computer networks (Internet, intranet, etc.). Such a download can be wired or wireless (e.g. via a WiFi network, a 3G, 4G, 5G or 6G connection, etc.).

Further advantages and embodiments of the disclosure are shown in the description and the accompanying drawing.

The disclosure is illustrated schematically in the drawing by means of embodiment examples and is described below with reference to the drawing.

### BRIEF DESCRIPTION OF THE DRAWINGS

FIG. 1 shows a block diagram of a drive system comprising a three-phase electrical machine and an inverter arrangement with current sensors and a computing unit, which is designed to carry out a method for monitoring an electrical machine, in embodiments.

FIG. 2 shows a flow chart of the method for monitoring an electrical machine, in embodiments.

FIGS. 3(a) and (b) show waveforms of fault-free currents in three phase windings and the waveform of the associated rationality factors.

FIGS. 4(a) and (b) show waveforms of the currents in three phase windings and the waveforms of the associated rationality factors in the event of an offset error.

FIGS. 5(a) and (b) show waveforms of the currents in three phase windings and the waveforms of the associated rationality factors in the event of a gain error, and

FIGS. 6(a) to (c) show waveforms of the currents in three phase windings and the waveforms of the associated rationality factors on two different scales in the event of a short circuit between phase windings.

### DETAILED DESCRIPTION

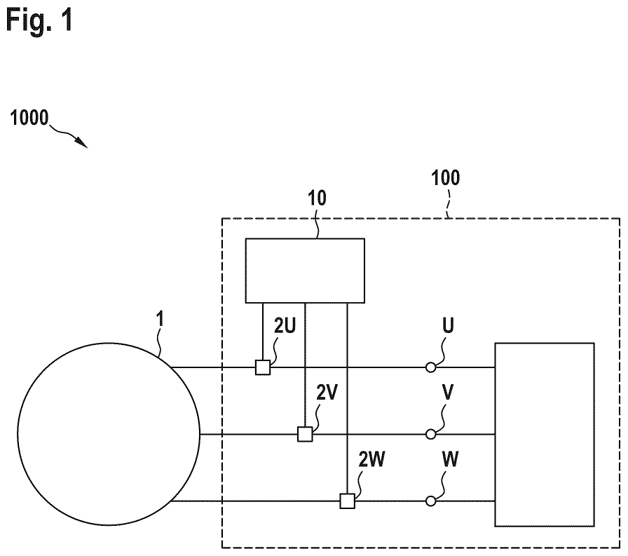

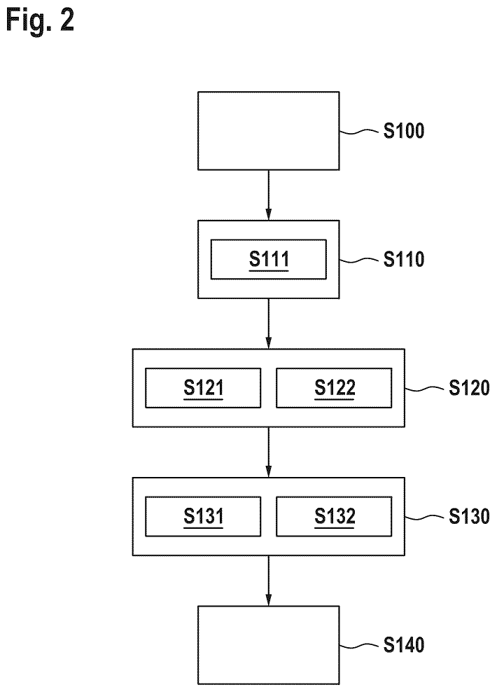

FIG. 1 shows a block diagram of a drive system 1000 comprising a three-phase electrical machine 1 and an inverter arrangement 100, which comprises a half-bridge (not shown) and a current sensor 2U, 2V, 2W for each phase winding U, V, W and a computing unit 10. The computing unit 10 is configured to carry out an embodiment of the method according to the disclosure. FIG. 2 shows a flow diagram of an embodiment of the method according to the disclosure. In the following, both figures will be described together.

Each phase winding U, V, W of the electrical machine 1 of the drive system 1000 is supplied with a phase current, which is in particular an alternating current, by the inverter arrangement 100 in motor operation. In generator mode, the current is generated in the electrical machine and output to the inverter arrangement, in particular for rectification.

In each case, a current sensor 2U, 2V, 2W measures the current, i.e. the waveform of the current strength, through one of the phase windings U, V, W and outputs the measured current to the computing unit 10. The computing unit 10, which is in particular a vehicle control unit, is connected to the inverter arrangement or the electric machine 1 and is configured to control the electric machine 1.

In a first step S100, the current in each of the three phase windings U, V, W is measured by one of the three current sensors 2U, 2V, 2W.

Subsequently, in step S110, a rationality factor is determined for each of the phase windings U, V, W as a function of the measured currents. For this purpose, a quotient is formed in step S111 for each of the phase windings U, V, W from the square of the current of one of the phase windings U; V; W and a sum of the squares of the currents of the other phase windings V, W; U, W; U, V.

In general, for multiphase machines, an equation for the rationality factors is given in equation (1). For a drive system 1000 with a three-phase electrical machine 1 with the phase windings U, V, W, the rationality factors are determined using equations (2) to (4).

Subsequently, in step S120, each of the determined rationality factors is compared with at least one threshold value S_{high}, S_{low} and in step S130, depending on the result of the comparison, it is determined whether there is a fault in the electrical machine 1 or not.

For this purpose, in step S121 each of the determined rationality factors is compared with a first threshold value S_{high} and in step S131 it is determined that a fault is present in the electrical machine 1 if one or more of the rationality factors exceed the first threshold value S_{high}. In other words, in the fault-free state, all rationality factors should always be below or at most at the first threshold value S_{high}.

Further, in step S122, each of the determined rationality factors is compared with a second threshold value S_{low} and in step S132 it is determined that a fault is present in the electrical machine 1 if not all of the rationality factors exceed the second threshold value S_{low} at least once in a predetermined time period T, which corresponds in particular to at least one or exactly one period length of the current waveform. In other words, in the fault-free state, each of the determined rationality factors should exceed the second threshold value at least once per period length.

If it is determined that there is a fault in the electrical machine 1, the electrical machine 1 is switched to a safe state by the computing unit 10 in step S140. For this purpose, the computing unit 10 can, for example, limit the maximum current that is supplied to each of the phase windings U, V, W or close all switches of a high side or a low side of the phase winding or phase windings for which the fault was determined or of all phase windings in the inverter arrangement 100.

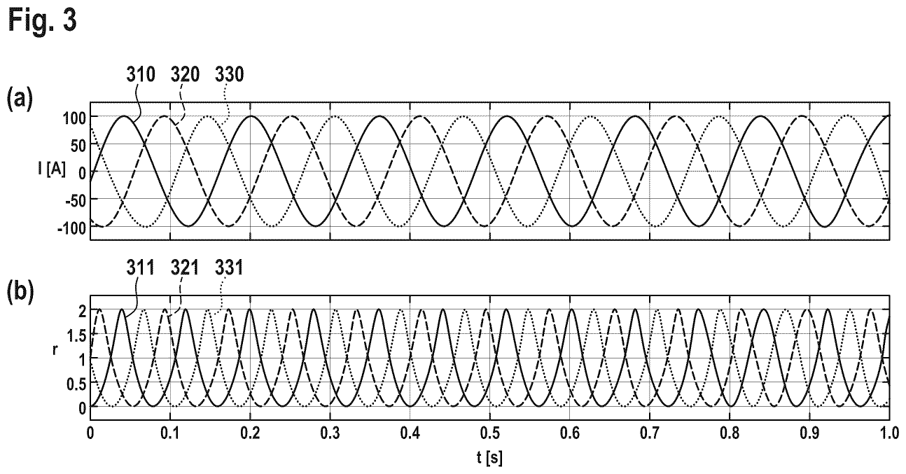

FIGS. 3(a) and (b) show a waveform I of a fault-free current in each of the three phase windings U, V, W and the waveform of the associated rationality factors r versus time t. The current waveforms are denoted 310, 320, 330 and the rationality factor waveforms are denoted 311, 321, 331.

For example, it can be assumed that the solid line 310 represents the current of the phase winding U measured by the current sensor 2U, the dashed line 320 represents the current of the phase winding V measured by the current sensor 2V and the dotted line 330 represents the current of the phase winding W measured by the current sensor 2W.

With the fault-free current, the current intensity I in each of the phase windings U, V, W ranges between a value of −100 A and 100 A, whereby the current intensity shown is only exemplary and depends on the power or torque of the electric machine 1. The current in each of the phase windings U, V, W has the same waveform, but is shifted by a phase angle of 120° to each other.

The rationality factor r ranges between a value of 0 and 2. The maxima of the rationality factor are reached when the current intensity reaches its positive or negative maximum.

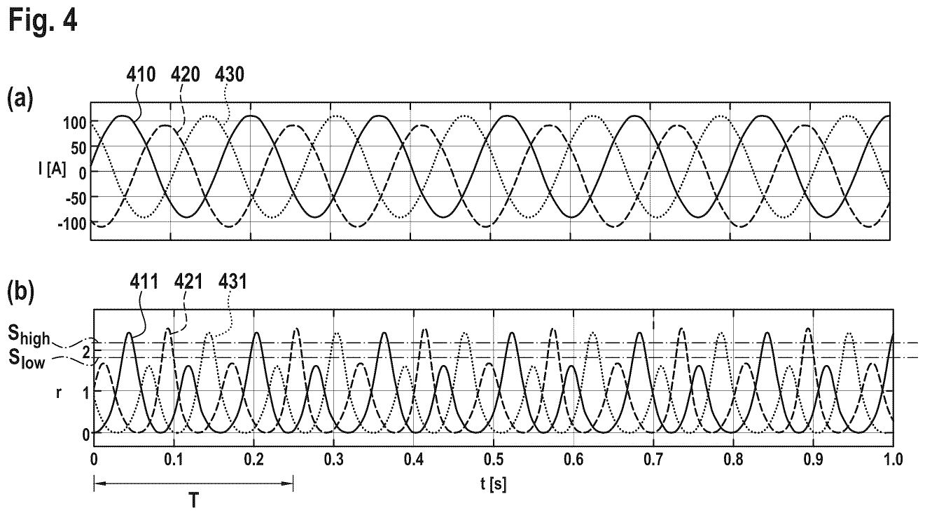

FIGS. 4(a) and (b) show the waveform of the currents I in each of the three phase windings U, V, W and the waveforms of the associated rationality factors r against time t the event of an offset error. The current waveforms are denoted 410, 420, 430 and the rationality factor waveforms are denoted 411, 421, 431.

E.g., the currents 410, 430 of the phase windings U and W have a positive offset and the current 420 of the phase winding V has a negative offset. This means that the currents of the phase windings U and W (solid line 410 and dotted line 430) move between values that are greater than −100 A and 100 A (approximately between −90 A and 110 A), while the current of the phase winding V (dashed line 420) moves between values that are less than −100 A and 100 A (approximately between −110 A and 90 A).

The rationality factors 411, 431 associated with the phase windings U and W each range between a value of 0 and approximately 2.3, with one of the two maxima in a period reaching a value of approximately 2.3 and the other maximum only reaching a value of approximately 1.6. The rationality factor 421 associated with the phase winding V ranges between a value of 0 and approximately 2.5, with one of the two maxima in a period reaching a value of approximately 2.5 and the other maximum only reaching a value of approximately 1.7.

If the first threshold value S_{high} for example, is set to a value of 2.2 and the second threshold value S_{low} is set to a value of 1.8, by the comparison of the rationality factors with the first threshold value S_{high} in step S121, it is determined that in the specified time period T each of the determined rationality factors exceeds the first threshold value S_{high} at least once. Therefore, in step S131, a fault is detected in the electrical machine 1.

When comparing the rationality factors of the phase windings U, V, W with the second threshold value S_{low} in step S122, it is determined that in the specified time period T, each of the rationality factors exceeds the second threshold value S_{low} at least once. In step S132, therefore, no fault is detected in the electrical machine 1.

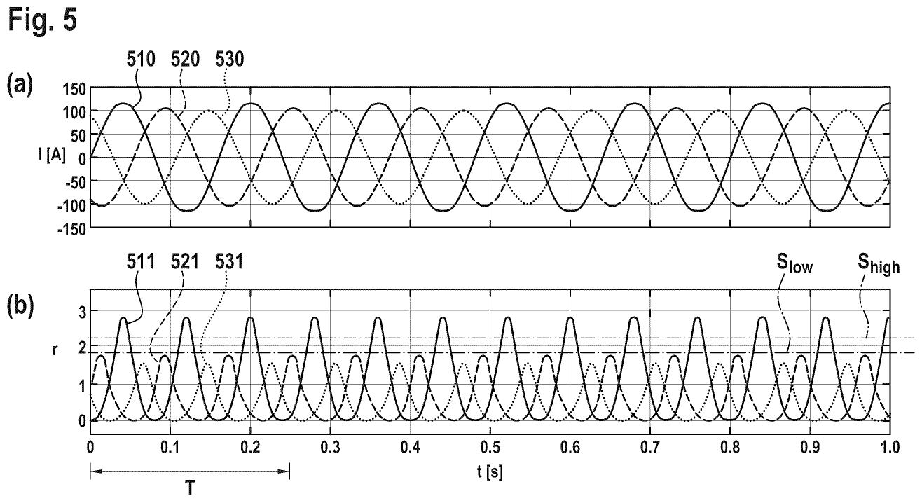

FIGS. 5(a) and (b) each show the waveform of the currents I in each of the three phase windings U, V, W and the waveform of the associated rationality factors r against time t the event of a gain error, i.e. the current does not oscillate between the intended maximum and minimum values of 100 A and −100 A, but between values whose magnitude is greater. The current waveforms are denoted 510, 520, 530 and the rationality factor waveforms are denoted 511, 521, 531.

The gain factor is increased in the phase windings U and V and is correct in the phase winding W. The current of the phase winding U (solid line 510) is between values that are clearly outside the range of −100 A and 100 A (especially between approximately −115 A and 115 A). The current of the phase winding V (dashed line 520), on the other hand, is only slightly increased and ranges between approximately −105 A and 105 A, and the current of the phase winding W (dotted line 530) is between −100 A and 100 A.

The rationality factor 511 associated with phase winding U ranges from 0 to approximately 2.8 and is therefore well above the error-free value of 2. The rationality factor 521 of phase winding V ranges from 0 to approximately 1.8. The rationality factor 531 of phase winding W ranges from 0 to approximately 1.5.

Again, e.g. the values 2.2 for the first threshold S_{high} and 1.8 for the second threshold S_{low} are determined.

In step S121, when comparing the rationality factor of the phase winding V shown with a dashed line 521 with the first threshold value S_{high}, it is determined that the rationality factor does not exceed the first threshold value S_{high} in the predetermined time period T of at least one waveform period, and when comparing it with the second threshold value S_{low} in step S122, it is determined that the rationality factor exceeds the second threshold value S_{low} at least once in the predetermined time period T of at least one waveform period.

In step S121, when comparing the rationality factor of the phase winding W shown with a dotted line 531 with the first threshold value S_{high}, it is determined that the rationality factor does not exceed the first threshold value S_{high} in the predetermined time period T of at least one waveform period. Furthermore, in step S122, when comparing the rationality factor with the second threshold value S_{low}, it is determined that the rationality factor does not exceed the value of the second threshold value S_{low} at least once in the predetermined time period T of at least one waveform period.

In step S121, when comparing the rationality factor of the phase winding U shown with a solid line 511 with the first threshold value S_{high}, it is determined that the rationality factor exceeds the first threshold value S_{high} at least once in the predetermined time period T of at least one waveform period. It is also determined in step S122 that the rationality factor exceeds the second threshold value S_{low} at least once in the predetermined time period T of at least one waveform period.

Thus, both in step S131 and in step S132, it is determined that a fault is present in the electrical machine 1 because at least one of the rationality factors (i.e. 511) exceeds the first threshold value S_{high} and at least one of the rationality factors (i.e. 521, 531) does not exceed the second threshold value S_{low} in the predetermined time period T.

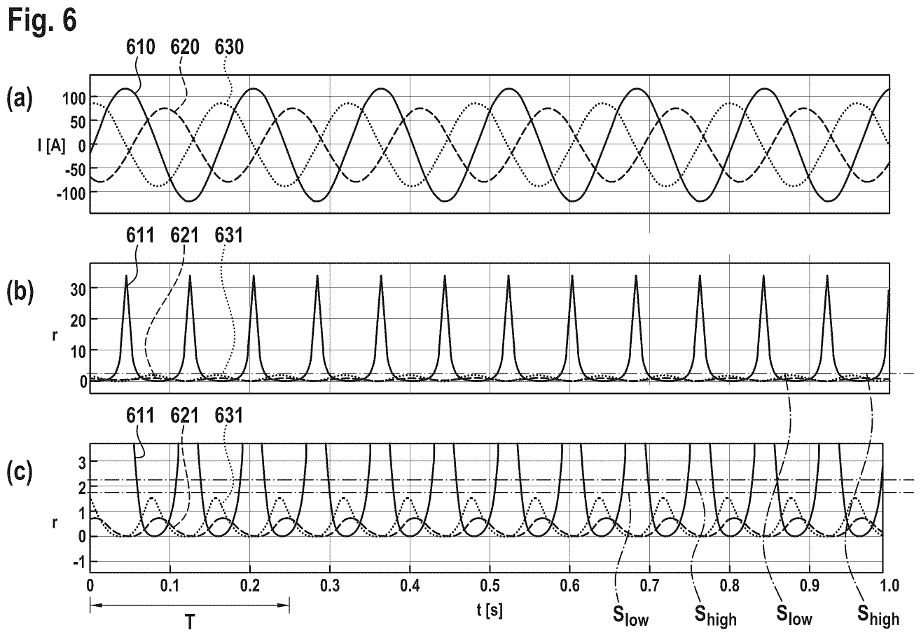

FIGS. 6(a) to (c) each show the waveform of the currents I in each of the phase windings U, V, W and the waveform of the associated rationality factors r on two different scales against time t in the event of a short circuit between the windings of different phase windings. The current waveforms are denoted 610, 620, 630 and the rationality factor waveforms are denoted 611, 621, 631.

The currents in the phase windings V and W (dashed line 620 and dotted line 630) are reduced compared to fault-free operation (V to approximately −70 A to 70 A, and W to approximately −80 A to 80 A) and the current in the phase winding U (solid line 610) is increased compared to fault-free operation (to approximately −115 A to 115 A). FIG. 6(b) shows the rationality factors 611, 621, 631 on a scale of 0 to approximately 40, while FIG. 6(c) shows the rationality factors 611, 621, 631 on a scale of 0 to approximately.

Again, the values 2.2 for the first threshold S_{high} and 1.8 for the second threshold S_{low} are used as examples.

In step S121, the comparison of the rationality factors with the first threshold value S_{high} shows that the rationality factors 621, 631 of the phase windings V and W do not exceed the first threshold value S_{high} in the predetermined time period T of at least one waveform. In step S122, when comparing the rationality factors 621, 631 of the phase windings V and W with the second threshold value S_{low}, it is determined that the rationality factor does not exceed the second threshold value S_{low} in the predetermined time period T of at least one waveform period (see FIG. 6 (c)).

In step S121, when comparing the rationality factor 611 of the phase winding U with the first threshold value S_{high}, it is determined that the rationality factor exceeds the first threshold value S_{high} by far. In step S122, when comparing the rationality factor 611 with the second threshold value S_{low}, it is determined that the rationality factor exceeds the second threshold value S_{low} at least once in the predetermined time period T.

Thus, both in step S131 and in step S132, it is determined that a fault is present in the electrical machine 1 because at least one of the rationality factors (i.e. 611) exceeds the first threshold value S_{high} in the predetermined time period T, and at least one of the rationality factors (i.e. 621, 631) does not exceed the second threshold value S_{low} in the predetermined time period T.

What is claimed:

1. A method of monitoring an electrical machine (1) having a stator comprising at least three phase windings (U, V, W) and a rotor, the method comprising:
measuring (S100) the current flowing through each of the at least three phase windings (U, V, W),
determining (S110) a rationality factor for each of the at least three phase windings (U, V, W) as a function of squares of the measured currents,
comparing (S120) the determined rationality factor for each of the at least three phase windings (U, V, W) with at least one threshold value (S_{high}, S_{low}), and determining (S130) whether a fault is present in the electrical machine (1) as a function of the comparison result.

2. The method according to claim 1, wherein the determining (S110) the rationality factor for each of the at least three phase windings (U, V, W) comprises:
determining (S111) the rationality factor as a function of a quotient of the square of the measured current of one of the at least three phase windings (U, V, W) and a sum of the squares of the currents of the others of the at least three phase windings (U, V, W).

3. The method according to claim 1, wherein the comparing (120) the determined rationality factor for each of the at least three phase windings (U, V, W) with at least one threshold value (S_{high}, S_{low}) and the determining (S130) whether there is a fault in the electrical machine (1) depending on the comparison result comprises:
comparing (S121) the determined rationality factor for each of the at least three phase windings (U, V, W) with a first threshold value (S_{high}), and
determining (S131) that a fault is present in the electrical machine (1) if at least one of the rationality factors exceeds the first threshold value (S_{high}).

4. The method according to claim 1, wherein the comparing (120) the determined rationality factor for each of the at least three phase windings (U, V, W) with at least one threshold value (S_{high}, S_{low}) and the determining (S130) whether there is a fault in the electrical machine (1) depending on the comparison result comprises:
comparing (S122) the determined rationality factor for each of the at least three phase windings (U, V, W) with a second threshold value (S_{low}), and
determining (S132) that a fault is present in the electrical machine (1) if not all rationality factors exceed the second threshold value (S_{low}) at least once in a predetermined time period (T).

5. The method according to claim 4, wherein the predetermined time period (T) corresponds to at least one, in particular exactly one, period length of the measured current waveforms.

6. The method according to claim 1, wherein the method further comprises:
switching (S140) the electrical machine (1) to a safe state when it is determined that there is a fault in the electrical machine (1).

7. A computing unit (10), which is configured to carry out all method steps of the method according claim 1.

8. An inverter arrangement (100) for controlling a electrical machine (1) having a stator comprising at least three phase windings (U, V, W) and a rotor, the inverter arrangement (100) having a half-bridge and a current sensor (2U, 2V, 2W) for each phase winding (U, V, W) of the at least three phase windings (U, V, W), which is configured to measure a current flowing through the phase winding (U, V, W), and a computing unit (10) which is configured to carry out all method steps of the method according claim 1.

9. A drive system (1000) comprising:
an electrical machine (1)) having a stator comprising at least three phase windings (U, V, W) and a rotor; and
an inverter arrangement (100) for controlling the electrical machine (1), having a half-bridge and a current sensor (2U, 2V, 2W) for each phase winding (U, V, W) of the at least three phase windings (U, V, W), which is configured to measure a current flowing through the phase winding (U, V, W), and a computing unit (10) which is configured to carry out all method steps of the method according claim 1.

10. A non-transitory machine-readable storage medium storing a computer program that, when executed by a computing unit (10), cause the computing unit (10) to perform the method of claim 1.
